(19) United States
(12) Patent Application Publication
(10) Pub. No.: US 2019/0081144 A1
(43) Pub. Date: Mar. 14, 2019

(54) SEMICONDUCTOR MEMORY DEVICE AND METHOD OF MANUFACTURING THE SAME

(71) Applicant: TOSHIBA MEMORY CORPORATION, Tokyo (JP)

(72) Inventors: Tatsunori ISOGAI, Yokkaichi Mie (JP); Shinji MORI, Nagoya Aichi (JP)

(73) Assignee: TOSHIBA MEMORY CORPORATION, Tokyo (JP)

(21) Appl. No.: 15/910,582

(22) Filed: Mar. 2, 2018

(30) Foreign Application Priority Data
Sep. 13, 2017 (JP) 2017-176167

(51) Int. Cl. H01L 29/40; H01L 27/11582

(52) U.S. Cl. CPC H01L 29/408; H01L 27/11582

(57) ABSTRACT

According to one embodiment, a semiconductor memory device includes a substrate, a stacked body, and a columnar portion. The columnar portion is provided within the stacked body, and includes a semiconductor portion extended in the first direction and a charge storage layer provided between the plural electrode films and the semiconductor portion. The columnar portion has a first region between the plural electrode films and the charge storage layer, a second region in which the charge storage layer is provided, and a third region between the semiconductor portion and the charge storage layer. The columnar portion includes impurities within the first region, the second region, and the third region. An average impurity concentration of the second region is higher than an average impurity concentration of the third region. An average impurity concentration of the third region is higher than an average impurity concentration of the first region.

### CROSS-REFERENCE TO RELATED APPLICATION

This application claims the benefit of and priority to Japanese Patent Application No. 2017-176167, filed Sep. 13, 2017, the entire contents of which are incorporated herein by reference.

### FIELD

Embodiments described herein relate generally to a semiconductor memory device and a method of manufacturing the same.

### BACKGROUND

There has been proposed a semiconductor memory device having a three-dimensional structure in which a memory hole is formed in a stacked body in which plural electrode films are stacked and a charge storage film and a channel are provided in the memory hole. The charge storage film has a function of trapping charges within the film and charges move between the charge storage film and the channel via an insulating film so that a write operation or an erase operation is performed. Improvements in operation characteristics of a memory cell with such a three-dimensional structure remain desired.

### DESCRIPTION OF THE DRAWINGS

FIG. 1 is a perspective view illustrating a semiconductor memory device according to a first exemplary embodiment.

FIG. 2 is a cross-sectional view illustrating the semiconductor memory device according to the first exemplary embodiment.

FIG. 3 is an enlarged view of region A of FIG. 1.

FIG. 4 is a diagram illustrating a characteristic of the semiconductor memory device according to the first exemplary embodiment.

FIG. 5 is a diagram illustrating a characteristic of the semiconductor memory device according to the first exemplary embodiment.

FIG. 6 is a cross-sectional view illustrating a method of manufacturing the semiconductor memory device according to the first exemplary embodiment.

FIG. 7 is a cross-sectional view illustrating the method of manufacturing the semiconductor memory device according to the first exemplary embodiment.

FIG. 8 is a cross-sectional view illustrating the method of manufacturing the semiconductor memory device according to the first exemplary embodiment.

FIG. 9 is a top plan view illustrating the method of manufacturing the semiconductor memory device according to the first exemplary embodiment.

FIG. 10 is a cross-sectional view illustrating the method of manufacturing the semiconductor memory device according to the first exemplary embodiment.

FIG. 11 is a cross-sectional view illustrating the method of manufacturing the semiconductor memory device according to the first exemplary embodiment.

FIG. 12 is a diagram illustrating a characteristic of a semiconductor memory device according to a reference example.

FIG. 13 is a diagram illustrating a characteristic of the semiconductor memory device according to the first exemplary embodiment.

FIG. 14 is a diagram illustrating a characteristic of the semiconductor memory device according to the first exemplary embodiment.

FIG. 15 is a cross-sectional view illustrating a semiconductor memory device according to a second exemplary embodiment.

FIG. 16 is a cross-sectional view illustrating the semiconductor memory device according to the second exemplary embodiment.

### DETAILED DESCRIPTION

In a three-dimensional structure in which a memory hole is formed in a stacked body in which plural electrode films are stacked and a charge storage film (or a charge storage layer) and a channel are provided in the memory hole, when a write operation and an erase operation are repeated, a defect may be generated in an insulating film provided between the charge storage film and the channel. When the charges within the charge storage film move in the state where the defect is generated, there is a problem in that data within a memory cell is lost and an operation characteristic of the memory cell is degraded.

An exemplary embodiment provides a semiconductor memory device with an improved operation characteristic of a memory cell, and a method of manufacturing the same.

In general, according to some embodiments, a semiconductor memory device may include a substrate, a stacked body, and a columnar portion. The stacked body may be provided on the substrate and includes plural electrode films, which are stacked to be spaced apart from one another in a first direction. The columnar portion may be provided within the stacked body, and may include a semiconductor portion extending in the first direction and a charge storage film provided between the plurality of electrode films and the semiconductor portion. The columnar portion may have a first region between the plural electrode films and the charge storage film, a second region in which the charge storage film is provided, and a third region between the semiconductor portion and the charge storage film. The columnar portion may include impurities within the first region, the second region, and the third region. The average impurity concentration in the second region may be higher than the average impurity concentration in the third region. The average impurity concentration in the third region may be higher than the average impurity concentration in the first region.

Hereinafter, each exemplary embodiment of the present disclosure will be described with reference to the drawings.

The drawings are schematic or conceptual, and the relationship between the thickness and the width of each portion, the ratio of sizes between the portions, and the like are necessarily the same as the actual ones. Further, even though the drawings represent the same portion, the sizes or ratios of the portion may be differently represented depending on the drawings.

In the present specification and respective drawings, elements similar to elements described with reference to preceding drawings will be denoted with the same reference numerals in the drawings, and detailed descriptions thereof may be properly omitted.

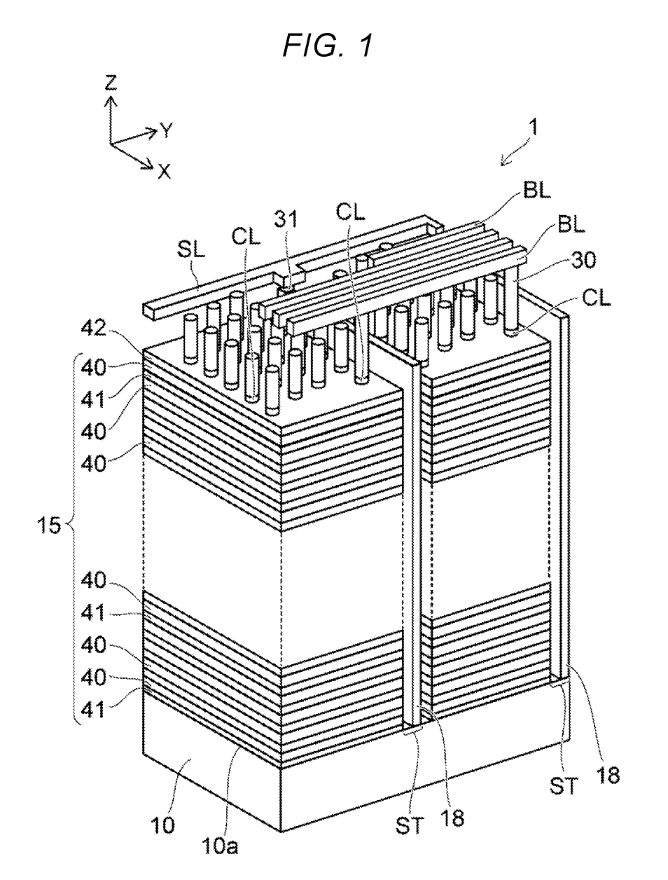

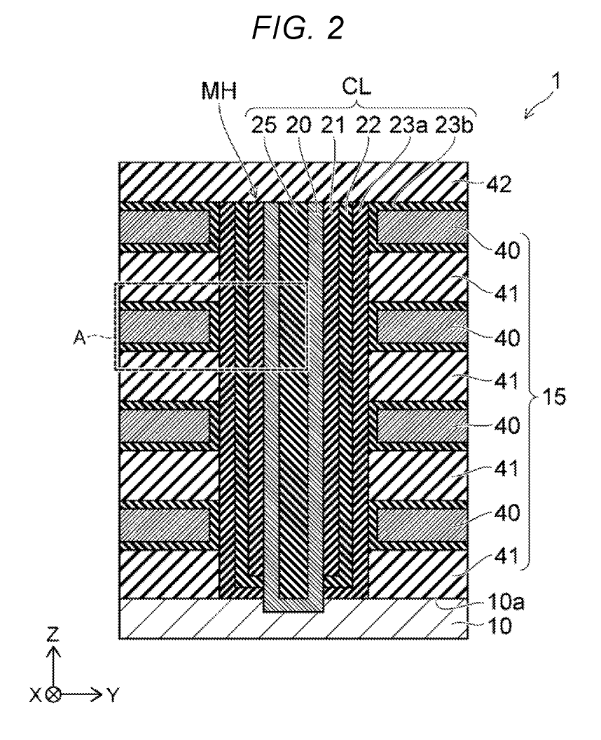

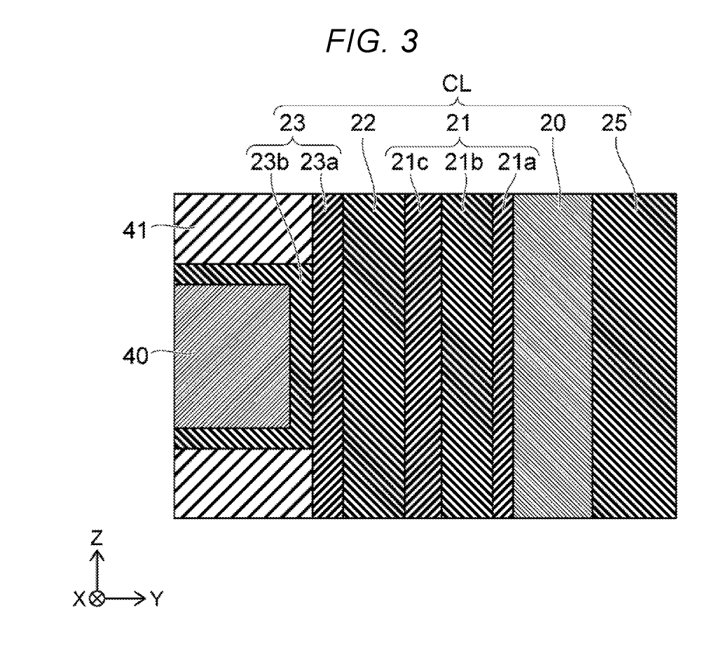

FIG. 1 is a perspective view illustrating a semiconductor memory device 1. FIG. 2 is a cross-sectional view illustrating the semiconductor memory device 1. FIG. 3 is an enlarged view of region A of FIG. 2.

As illustrated in FIG. 1 and FIG. 2, the semiconductor memory device 1 is provided with a substrate 10. The substrate 10 maybe a semiconductor element, and may include silicon (Si), such as single crystal silicon.

Herein, two directions which are parallel to an upper surface 10a of the substrate 10 and are orthogonal to each other will be referred to as an X-axis direction and a Y-axis direction (see FIG. 1). A direction which is orthogonal to both directions of the X-axis direction and the Y-axis direction will be referred to as a Z-axis direction (see FIG. 1).

As illustrated in FIG. 1, the semiconductor memory device 1 is provided with a stacked body 15, plural columnar portions CL, and wiring units 18. The stacked body 15 is provided on the substrate 10. The stacked body 15 includes plural electrode films 40 and plural insulating films 41. The stacking direction of the stacked body 15 corresponds to the Z-axis direction.

The plural electrode films 40 may be configured with a source-side selection gate, a word line, and a drain-side selection gate. For example, in the plural electrode films 40, the source-side selection gate and the drain-side selection gate correspond to the lowermost electrode film 40 and the uppermost electrode film 40, respectively, and the word line corresponds to an electrode film 40 located between the lowermost electrode film and the uppermost electrode film. Further, the number of stacked films of the electrode films 40 is arbitrary.

The electrode film 40 may include a conductive material. For example, the electrode film 40 includes a metal such as tungsten (W). The electrode film 40 may be provided with a main body portion and a barrier metal layer. The main body portion may be formed of, for example, tungsten. The barrier metal layer may be formed of, for example, a titanium nitride (TiN) and may cover the surface of the main body portion.

As illustrated in FIG. 1, an insulating film 41 is provided between electrode films 40. The insulating film includes, for example, a silicon oxide (SiO). The insulating film 41 serves as an element isolation film in the electrode films 40.

As illustrated in FIG. 1, an insulating film 42 is provided on the stacked body 15. The insulating film 42 includes, for example, a silicon oxide.

As illustrated in FIG. 2. The columnar portions CL are provided within the stacked body 15. The columnar portions CL are respectively located within memory holes MH (through via holes) provided in the stacked body 15, and extend within the stacked body 15 in the Z-axis direction. When the plural columnar portions CL are provided, for example, the plural columnar portions CL are arranged in a lattice shape in the X-axis direction and the Y-axis direction.

As illustrated in FIG. 2 and FIG. 3, each columnar portion CL includes a core portion 25, a channel 20, a tunnel insulating film 21, a charge storage film (or charge storage layer) 22, and a block insulating film 23. The block insulating film 23 includes an insulating film 23a and an insulating film 23b.

The core portion 25 includes, for example, a silicon oxide. The core portion 25 has, for example, a cylindrical shape.

As illustrated in FIG. 2, the channel 20 is provided on the external surface of the core portion 25. The channel 20 may be a semiconductor portion, and may include, for example, silicon. The channel 20 may include, for example, polysilicon that is obtained by crystallizing amorphous silicon. The channel 20 has, for example, a cylindrical shape.

A plug (not illustrated) formed by silicon and the like may be provided at an upper end of the core portion 25. A peripheral portion of the plug may be surrounded by the channel 20, and as illustrated in FIG. 1, and an upper end of the plug may be connected to a bit line BL via a contact 30.

As illustrated in FIG. 2 and FIG. 3, the tunnel insulating film 21 is provided on an external surface of the channel 20. The tunnel insulating film 21 has, for example, a cylindrical shape. As illustrated in FIG. 3, the tunnel insulating film 21 includes an insulating film 21a, an insulating film 21b, and an insulating film 21c.

As illustrated in FIG. 3, the insulating film 21a is located on the external surface of the channel 20, and includes, for example, silicon oxide. The insulating film 21b is located on an external surface of the insulating film 21a, and includes, for example, silicon oxynitride (SiON). The insulating film 21c is located on an external surface of the insulating film 21b, and includes, for example, silicon oxide.

As illustrated in FIG. 3, the core portion 25, the channel 20, the insulating film 21a, the insulating film 21b, the insulating film 21c, the charge storage film 22, the insulating film 23a, and the insulating film 23b are disposed in the this order as approaching the electrode film 40 in the Y-axis direction.

In the example illustrated in FIG. 3, the tunnel insulating film 21 is configured with three films including the insulating films 21a, 21b, and 21c, but the number of films constituting the tunnel insulating film 21 is arbitrary. For example, the tunnel insulating film 21 may be configured with a single film, such as a silicon oxide film.

The tunnel insulating film 21 may be a potential barrier between the charge storage film 22 and the channel 20. During the write operation, electrons are tunneled into the charge storage film 22 from the channel 20 in the tunnel insulating film 21, so that information is written. In the meantime, during the erase operation, holes are tunneled from the channel 20 to the charge storage film 22 in the tunnel insulating film 21 to cancel electron charge, so that stored information is erased.

As illustrated in FIG. 3, the charge storage film 22 is provided on the external surface of the tunnel insulating film 21 (insulating film 21c). The charge storage film 22 includes, for example, a silicon nitride (SiN). The charge storage film 22 has, for example, a cylindrical shape.

A memory cell including the charge storage film 22 may be formed at an intersection of the channel 20 and the electrode film 40 (word line). The charge storage film 22 may have a trap site which traps charges within the film 22. The threshold voltage of the memory cell may vary depending on existence/non-existence of charges trapped in the trap site and the quantity of trapped charge so that the memory cell can store information.

As illustrated in FIG. 3, the insulating film 23a is provided on an external surface of the charge storage film 22. The insulating film 23a includes, for example, silicon oxide. The insulating film 23a has, for example, a cylindrical shape. For example, the insulating film 23a protects the charge storage film 22 from being etched when the electrode film 40 is formed. Further, the insulating film 23a may prevent the electrons injected from the channel 20 during the write operation from directly passing through the charge storage film 22 and directly penetrating the electrode film 40 side (for example, the word line side). Further, the insulating film 23a may prevent the electrons from being injected from the electrode film 40 side (for example, the word line side) during the erase operation.

As illustrated in FIG. 3, the insulating film 23b is provided between the insulating film 23a and the electrode film 40, and between the insulating film 41 and the electrode film 40. The insulating film 23b includes, for example, aluminum oxide (AlO).

In the example illustrated in FIG. 3, the block insulating film 23 is configured with two films including the insulating films 23a and 23b, but the number of films constituting the block insulating film 23 is arbitrary. For example, the block insulating film 23 may be configured with a single film, such as a silicon oxide film. Further, when the block insulating film 23 is configured with plural films, a stacked structure with a high-dielectric (High-k) insulating film material may be used. Examples of the high-dielectric insulating film material include, but are not limited to, aluminum oxide (AlOx), hafnium oxide (HfOx), and lanthanum aluminum oxide (LaAlOx).

As illustrated in FIG. 1, the wiring unit 18 is provided within a slit ST formed in the stacked body 15. The lower end of the wiring unit 18 is located on the substrate 10. An upper end of the wiring unit 18 is connected with a source line SL via a contact 31.

In the semiconductor memory device 1, the plural memory cells each of which includes the charge storage film 22 maybe arranged in a three-dimensional lattice shape in the X-axis direction, the Y-axis direction, and the Z-axis direction, and each memory cell may store data.

Next, a characteristic of the columnar portion CL will be described.

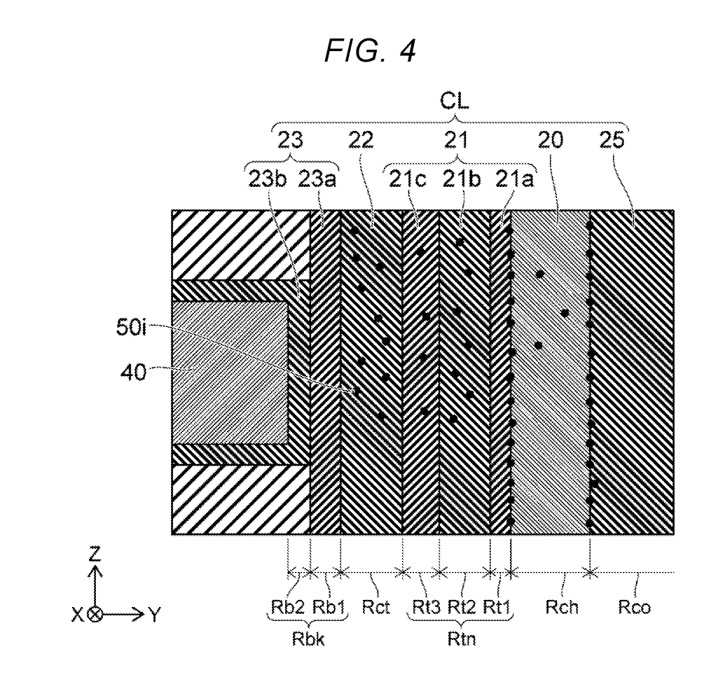

FIG. 4 is a diagram illustrating a characteristic of the semiconductor memory device according to the first exemplary embodiment.

FIG. 4 schematically illustrates an exemplary embodiment in which impurities 50i are included in the columnar portion CL, and the region illustrated in FIG. 4 corresponds to the region illustrated in FIG. 3.

In the example of FIG. 4, the columnar portion CL may be configured such that, for example, the core portion 25 includes a silicon oxide, the channel 20 includes polysilicon, the insulating film 21a includes a silicon oxide, the insulating film 21b includes a silicon oxynitride, the insulating film 21c includes a silicon oxide, the charge storage film 22 includes a silicon nitride, the insulating film 23a includes a silicon oxide, and the insulating film 23b includes an aluminum oxide.

As illustrated in FIG. 4, the impurities 50i are included in the columnar portion CL. Herein, the impurities 50i may correspond to an element capable of terminating a dangling bond of silicon Si, except for hydrogen (H). For example, the impurities 50i may include heavy hydrogen (D), fluorine (F), carbon (C), nitrogen (N), or selenium (Se).

The impurities 50i within the columnar portion CL may be a compound having a predetermined functional group, for example, a cyano group (—CN).

As illustrated in FIG. 4, the impurities 50i are included in each of a region Rco of the core portion 25, a region Rch of the channel 20, a region Rtn of the tunnel insulating film 21, a region Rct of the charge storage film 22, and a region Rbk of the block insulating film 23 at a predetermined concentration. Further, the region Rtn of the tunnel insulating film 21 has a region Rt1 of the insulating film 21a, a region Rt2 of the insulating film 21b, and a region Rt3 of the insulating film 21c. The region Rbk of the block insulating film 23 has a region Rb1 of the insulating film 23a and a region Rb2 of the insulating film 23b.

Next, a concentration distribution of the impurities 50i within the columnar portion CL will be described.

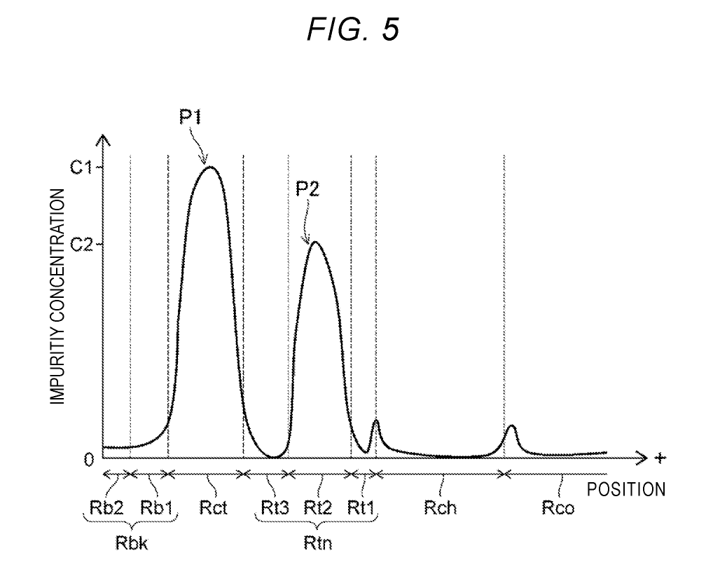

FIG. 5 is a diagram illustrating a characteristic of the semiconductor memory device according to the first exemplary embodiment.

FIG. 5 represents a concentration distribution of the impurities 50i within the regions Rco, Rch, Rtn (Rt1, Rt2, and Rt3), Rct, and Rbk (Rb1 and Rb2). In FIG. 5, the vertical axis represents an impurity concentration, and the horizontal axis represents a position from the electrode film 40. In FIG. 5, the horizontal axis represents positions corresponding to the regions Rco, Rch, Rtn (Rt1, Rt2, and Rt3), Rct, and Rbk (Rb1 and Rb2). In FIG. 5, the horizontal axis represents positions within the columnar portion CL (for example, positions within the columnar portion CL in the Y-axis direction). As the positions approach the plus (+) side in the horizontal axis, the positions become farther apart from the electrode film 40. As the positions approach zero in the horizontal axis, the positions become closer to the electrode film 40.

The concentration represented in FIG. 5 is, for example, the impurity concentration per volume (cm³) calculated from a planar shape cut from the electrode film 40 to the core portion 25.

In the example semiconductor memory device whose characteristics are illustrated FIG. 5, the columnar portion CL is configured such that the core portion 25 includes silicon oxide, the channel 20 includes polysilicon, the insulating film 21a includes silicon oxide, the insulating film 21b includes silicon oxynitride, the insulating film 21c includes silicon oxide, the charge storage film 22 includes silicon nitride, the insulating film 23a includes silicon oxide, and the insulating film 23b includes aluminum oxide.

According to the concentration distribution illustrated in FIG. 5, a peak distribution P1 is formed in the region Rct of the charge storage film 22, and a peak distribution P2 is formed in the region Rt2 of the insulating film 21b. The maximum value C1 (a maximum value of the impurity concentration) of the peak distribution P1 is larger than the maximum value C2 (a maximum value of the impurity concentration) of the peak distribution P2. Further, the maximum value C1 of the peak distribution P1 corresponds to the maximum value by the concentration distribution of the impurities 50i.

According to the concentration distribution illustrated in FIG. 5, the average impurity concentration in the region Rct of the charge storage film 22 is higher than the average impurity concentration in the region Rtn of the tunnel insulating film 21. That is, the average impurity concentration in the region Rct is higher than the average impurity concentration in the region Rtn that is a combined region of the region Rt1, the region Rt2, and the region Rt3. Further, the average impurity concentration is an average impurity concentration per volume (cm³) calculated from a planar shape cut in the Z-axis direction from the electrode film 40 to the core portion 25, which is the region intersecting the electrode film 40 in the X-Y plane. That is, in the exemplary embodiment whose characteristics are illustrated in FIG. 5, the impurity concentration is an average impurity concentration per volume of each region within the same Z-axis range as the electrode film 40. Further, in the exemplary embodiment whose characteristics are illustrated in FIG. 5, the average impurity concentration per volume is calculated based on the planar shape, but the method of calculating the average impurity concentration is not particularly limited.

According to the concentration distribution illustrated in FIG. 5, an average impurity concentration in the region Rtn of the tunnel insulating film 21 is higher than an average impurity concentration in the region Rbk of the block insulating film 23. That is, the average impurity concentration of the region Rt1, the region Rt2, and the region Rt3 is higher than an average impurity concentration of the region Rbk that is the combined region of the region Rb1 and the region Rb2.

Next, a method of manufacturing the semiconductor memory device according to some exemplary embodiments will be described.

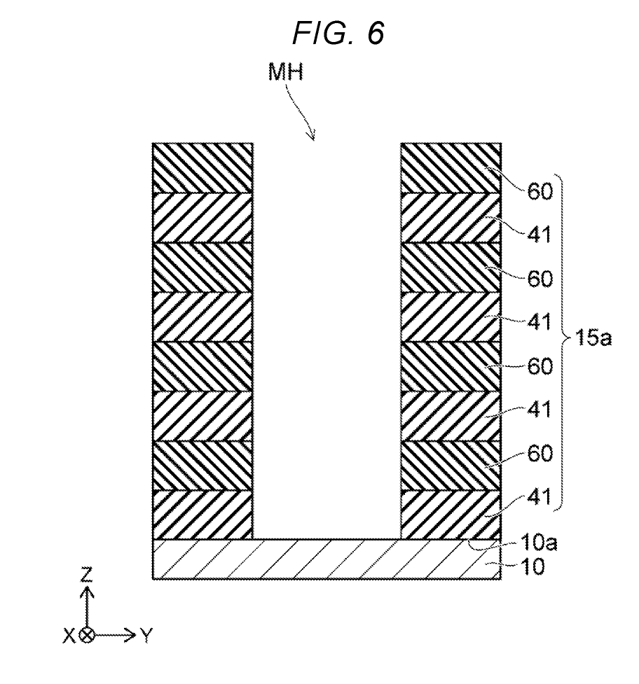

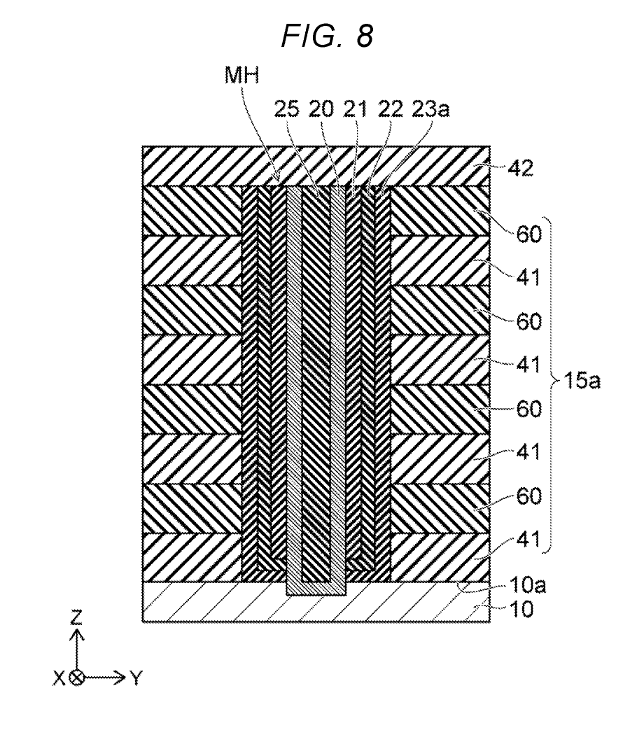

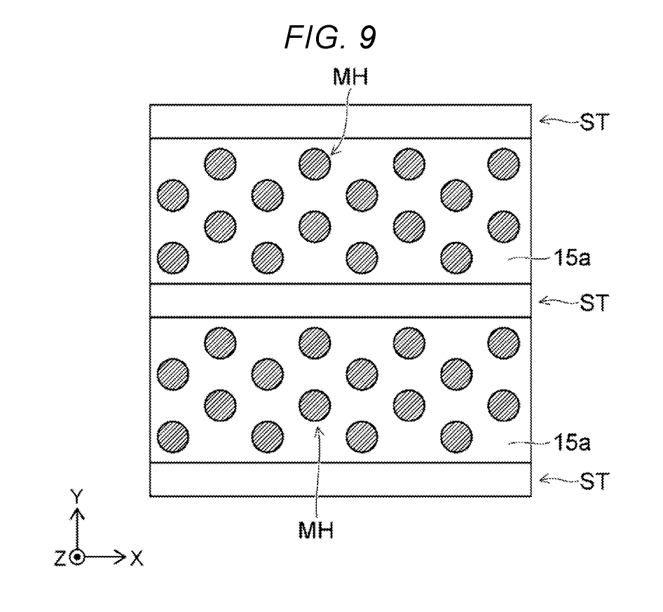

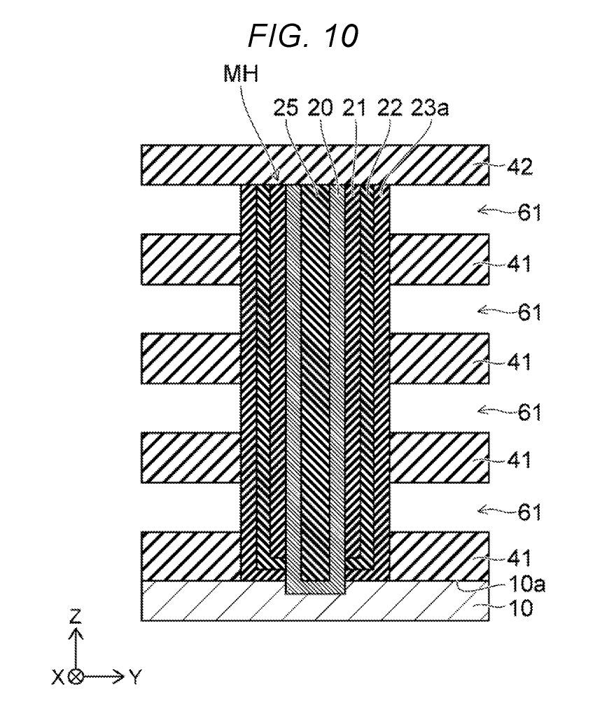

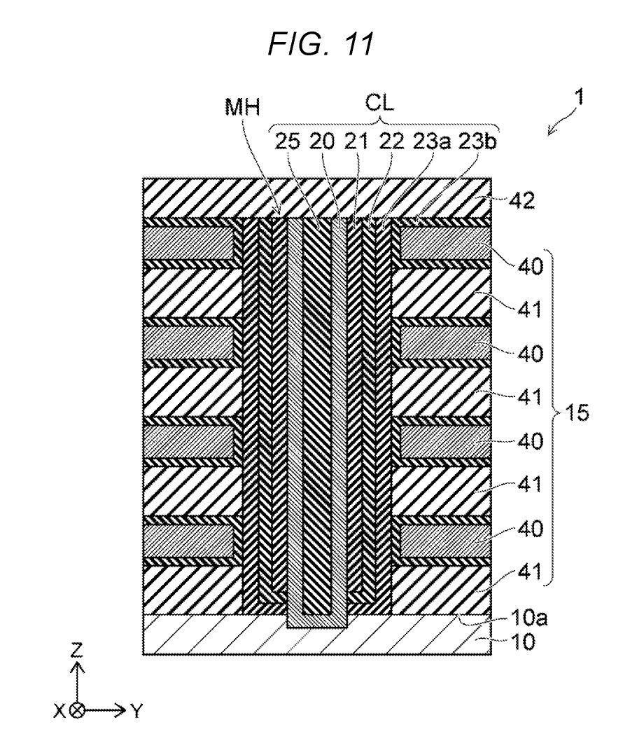

FIG. 6 to FIG. 11 are diagrams illustrating a method of manufacturing the semiconductor memory device 1. FIG. 6 to FIG. 8, FIG. 10, and FIG. 11 illustrate the region corresponding to FIG. 2. FIG. 9 is a top plan view, in which a structure after the process of FIG. 8 is viewed in the Z-axis direction.

First, as illustrated in FIG. 6, a stacked body 15a is formed by alternately stacking insulating films 41 and sacrifice films 60 on the substrate 10 in the Z-axis direction by, for example, an atomic layer deposition (ALD) method or a chemical vapor deposition (CVD) method. The insulating films 41 are formed of, for example, a silicon oxide, and the sacrifice films 60 are formed of, for example, a silicon nitride.

Subsequently, a memory hole MH (see FIG. 6) is formed in the stacked body 15a by, for example, a reactive ion etching (RIE) method. As illustrated in FIG. 6, the memory hole MH passes through the stacked body 15a and reaches the substrate 10. When the plural memory holes MH are formed, the plural memory holes MH are formed in, for example, a lattice shape when viewed in the Z-axis direction.

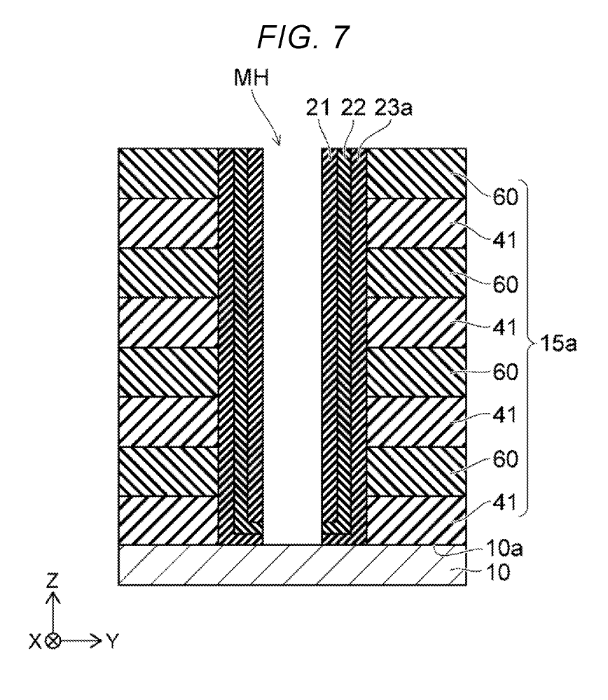

Next, as illustrated in FIG. 7, the insulating film 23a is formed on the inner wall surface of the memory hole MH by, for example, the ALD method or a low pressure chemical vapor deposition (LPCVD) method. The insulating film 23a is formed of, for example, silicon oxide.

Subsequently, as illustrated in FIG. 7, the charge storage film 22 is formed on the insulating film 23a within the memory hole MH by, for example, the ALD method or the LPCVD method. The charge storage film 22 is formed of, for example, silicon nitride.

Subsequently, as illustrated in FIG. 7, the tunnel insulating film 21 is formed on the charge storage film 22 within the memory hole MH by, for example, the ALD method or the LPCVD method. The tunnel insulating film 21 is formed by, for example, sequentially stacking three films including the insulating films 21c, 21b, and 21a on a lateral surface of the charge storage film 22 as illustrated in FIG. 3. The tunnel insulating film 21 may be a single film, such as a silicon oxide film.

For example, as illustrated in FIG. 7, after the insulating film 23a, the charge storage film 22 and the tunnel insulating film 21 are sequentially formed on the inner surface of the memory hole MH, the upper surface 10a of the substrate 10 located within the memory hole MH is exposed by etching.

Subsequently, the impurities 50i (see FIG. 4) are introduced into the tunnel insulating film 21, the charge storage film 22, and the insulating film 23a via the memory hole MH by, for example, an ion implantation method. The impurities 50i may be heavy hydrogen, fluorine, carbon, nitrogen, selenium, etc. As the impurities 50i, a compound having a cyano group may be introduced.

The impurities 50i may be introduced so as to form the concentration distribution illustrated in FIG. 5. That is, the impurities 50i maybe introduced such that the average impurity concentration in the region Rct of the charge storage film 22 is higher than the average impurity concentration in the region Rtn of the tunnel insulating film 21, and the average impurity concentration in the region Rtn of the tunnel insulating film 21 is higher than the average impurity concentration in the region Rbk of the block insulating film 23.

The impurities 50i may be ionized, accelerated, and introduced into the tunnel insulating film 21, the charge storage film 22, and the insulating film 23a. As a processing condition by the ion implantation method, for example, the acceleration voltage is in the range of 1 keV or more and 10 keV or less, and the dose amount is, for example, in the range of 1E14 cm-² or more and 1E16 cm-² or less, and the tilt angle is, for example, about 7°.

In the case where the ion implantation method is used, upon considering the aspect ratio of the memory hole MH and the shape (for example, a cylindrical shape) of the memory hole MH, the tilt angle or the twist angle is not uniform, and a split implantation in which the tilt angle or the twist angle is changed, may be performed.

For example, the impurities 50i may be introduced by implanting ions using a beam line ion implantation device. The impurities 50i may be introduced by plasma doping using a plasma doping device. The plasma doping device may be used to implant ions to the stacked body 15a having the three-dimensional structure, so that the ion implantation processing may be performed within a short time. Accordingly, productivity may be improved.

Hereinafter, another method of introducing the impurities 50i will be described.

For example, the impurities 50i may be introduced into the tunnel insulating film 21, the charge storage film 22, and the insulating film 23a (see FIG. 7) by heat-treating the substrate 10 in a gas atmosphere including the impurities 50i. As a condition of the heat treatment, for example, in an atmosphere including gas, such as heavy hydrogen, fluorine, or hydrogen selenide (HSe), temperature is in the range of 400° C. or higher and 900° C. or lower, and the processing time is in the range of 10 minutes or longer and two hours or shorter. The pressure may be either reduced pressure or atmosphere pressure. Further, since a chemical reaction is performed at a low temperature, pressurization may be performed, and in this case, for example, the heat treatment is performed under the pressure in the range of 5 atmospheres or more and 20 atmospheres or less.

Instead of the gas including the impurities 50i, a compound having a cyano group may be introduced into the tunnel insulating film 21, the charge storage film 22, and the insulating film 23a by heat-treating the substrate 10 in an atmosphere including gas of hydrogen cyanide (HCN).

The heat treatment may be performed whenever each of the insulating film 23a, the charge storage film 22, and the tunnel insulating film 21 is formed, and may be performed after all of the insulating film 23a, the charge storage film 22, and the tunnel insulating film 21 are formed. Further, after the channel 20 is formed or the core portion 25 is formed (see FIG. 8), the heat treatment may be performed.

Through the foregoing heat treatment, the impurities 50i can be introduced so as to form the concentration distribution illustrated in FIG. 5. That is, the impurities 50i may be introduced such that the average impurity concentration in the region Rct of the charge storage film 22 is higher than the average impurity concentration in the region Rtn of the tunnel insulating film 21, and the average impurity concentration in the region Rtn of the tunnel insulating film 21 is higher than the average impurity concentration in the region Rbk of the block insulating film 23.

Subsequently, still another method of introducing the impurities 50i will be described.

For example, a predetermined gas may be made to flow during the film formation process of the insulating film 23a, the charge storage film 22, and the tunnel insulating film 21, and a gas including the impurities 50i may be made to flow simultaneously with the film formation of the insulating film 23a, the charge storage film 22, and the tunnel insulating film 21.

For example, when the charge storage film 22 is formed of a silicon nitride film, dichlorosilane (SiH₂Cl₂) may be used as an Si source and ammonia (NH₃) is as a nitriding agent, and the gases may be made to alternately flow at a temperature in the range of 500° C. or higher and 700° C. or lower, and at a pressure in the range of of 1 Torr or less. Accordingly, the charge storage film 22 having a film thickness (a thickness in the Y-axis direction), for example, in the range of 5 nm or more and 10 nm or less may be formed. Further, when the charge storage film 22 is formed, the gas including the impurities 50i may be made to flow as different gas from the Si source and the nitriding agent, so that the impurities 50i may be introduced into the film simultaneously with the film formation. When the series of gas processes are performed, an additional process, such as an ion implantation or a heat treatment, for introducing the impurities 50i does not need to be performed.

Through the foregoing gas processing, the impurities 50i can be introduced so as to form the concentration distribution illustrated in FIG. 5. That is, the impurities 50i may be introduced so that the average impurity concentration in the region Rct of the charge storage film 22 is higher than the average impurity concentration in the region Rtn of the tunnel insulating film 21, and the average impurity concentration in the region Rtn of the tunnel insulating film 21 is higher than the average impurity concentration in the region Rbk of the block insulating film 23.

After the impurities 50i are introduced by any one of the foregoing methods, as illustrated in FIG. 8, the channel 20 is formed on the tunnel insulating film 21 in the memory hole MH by, for example, an ALD method or a CVD method. The channel 20 is formed of, for example, polysilicon. For example, the channel 20 is formed by forming amorphous silicon at a temperature of about 500° C. and then crystallizing the amorphous silicon by performing a heat treatment at 800° C. or higher.

Subsequently, as illustrated in FIG. 8, the core portion 25 is formed on the channel 20 in the memory hole MH by, for example, an ALD method or a CVD method. The core portion 25 is formed of, for example, a silicon oxide.

Subsequently, as illustrated in FIG. 8, the insulating film 42 is formed on the stacked body 15a. The insulating film 42 is located on (or covers) the core portion 25, the channel 20, the tunnel insulating film 21, the charge storage film 22, and the insulating film 23a.

Next, as illustrated in FIG. 9, the slits ST extending in the X-axis direction and the Z-axis direction are formed in the stacked body 15a by, for example, an RIE method. When the plural memory holes MH are formed, the plural memory holes MH may be arranged in a lattice shape between the slits ST. In the Z-axis direction, the slit ST may pass through the insulating film 42 and the stacked body 15a, and reaches the substrate 10 (see FIG. 1).

Next, as illustrated in FIG. 10, the sacrifice films 60 of the stacked body 15a are selectively removed via the slits ST (see FIG. 9) by, for example, a wet etching method. Cavities 61 are formed in the stacked body 15a by the removal of the sacrifice films 60. For example, when the sacrifice films 60 are formed of a silicon nitride, phosphoric acid may be used as an etching agent for the wet etching. The insulating film 23a may serve as an etching stopper, and protect the charge storage film 22 from being etched.

Next, as illustrated in FIG. 11, the insulating film 23b is formed on an internal surface of the cavity 61 by, for example, an ALD method or a CVD method. The insulating film 23b is formed of, for example, an aluminum oxide. Accordingly, a block insulating film 23 including the insulating film 23a and the insulating film 23b is formed. Further, the columnar portion CL including the core portion 25, the channel 20, the tunnel insulating film 21, the charge storage film 22, the insulating film 23a, and the insulating film 23b is formed.

Subsequently, as illustrated in FIG. 11, the electrode film 40 is formed on the insulating film 23b by, for example, an ALD method or a CVD method. For example, the electrode film 40 formed of a deposited material including titanium nitride and tungsten is formed. Accordingly, the stacked body 15 including the plural electrode films 40 and the plural insulating films 41 is formed.

Then, a contact and a bit line (e.g., BL in FIG. 1) connected to the channel 20 may be formed on the columnar portion CL.

In this way, the semiconductor memory device 1 according to the exemplary embodiments illustrated in FIG. 1 to FIG. 11 is manufactured.

With the semiconductor memory device 1 according to the exemplary embodiments illustrated in FIG. 1 to FIG. 11, a data storage property of the charge storage film 22 is improved. Hereinafter, the reason will be described.

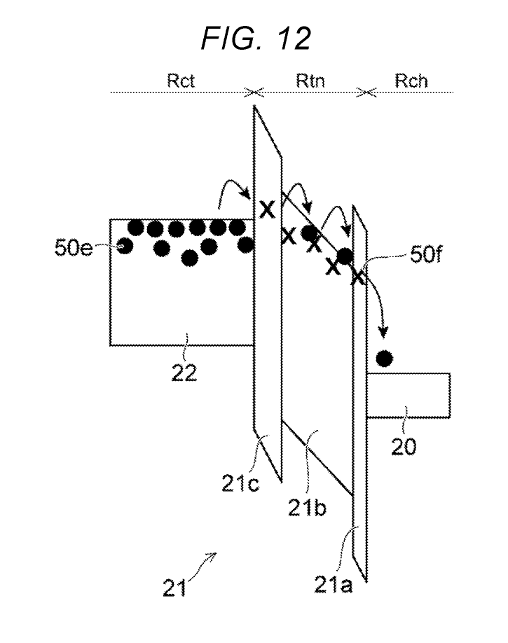

FIG. 12 is a diagram illustrating a characteristic of a semiconductor memory device according to a reference example.

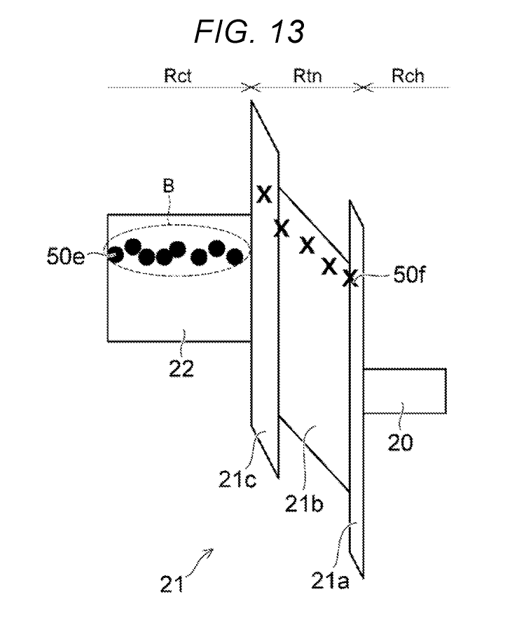

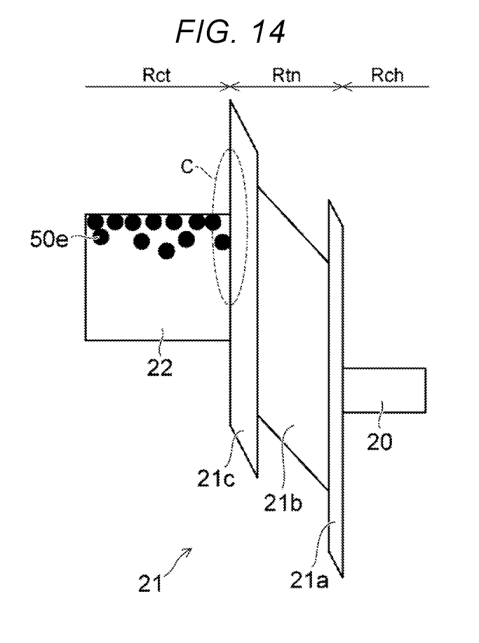

FIG. 13 and FIG. 14 are diagrams illustrating a characteristic of the semiconductor memory device according to the first exemplary embodiment.

FIG. 12 to FIG. 14 schematically illustrate band structures within the region Rct of the charge storage film 22, the region Rtn of the tunnel insulating film 21, and the region Rch of the channel 20 in the state where the charges are held within the charge storage film 22, respectively.

In a semiconductor memory device having a three-dimensional structure, a charge storage film has a function of trapping charges in the film, and the charges move between the charge storage film and a channel via a tunnel insulating film, so that a write operation or an erase operation is performed. When the write operation or the erase operation is repeated, a defect or the like may be generated in the tunnel insulating film and the like. The defect is generated, for example, when hydrogen atoms are introduced during the manufacturing of the semiconductor memory device and the hydrogen atoms within the element, such as the tunnel insulating film, are eliminated due to the electrical stress of the write operation or the erase operation.

For example, as illustrated in FIG. 12, when the write operation or the erase operation is repeated, defects 50f are generated within the tunnel insulating film 21 (the insulating films 21a, 21b, and 21c). Electrons 50e within the charge storage film 22 move to the channel 20 via the defects 50f within the tunnel insulating film 21. Accordingly, data within the memory cell loses, and an operation characteristic of the memory cell is degraded.

In the semiconductor memory device 1 of the exemplary embodiments illustrated in FIG. 1 to FIG. 11, in the columnar portion CL containing the impurities 50i, the average impurity concentration in the region Rct of the charge storage film 22 is higher than the average impurity concentration in the region Rtn of the tunnel insulating film 21. Further, the average impurity concentration in the region Rtn of the tunnel insulating film 21 is higher than the average impurity concentration in the region Rbk of the block insulating film 23.

In the exemplary embodiments illustrated in FIG. 1 to FIG. 11, when the impurities 50i are contained in the charge storage film 22 and the tunnel insulating film 21 with the foregoing concentration relationship, the charges stored in the charge storage film 22 are difficult to be eliminated, so that a data storage property can be improved.

For example, as illustrated in FIG. 13, the impurities 50i are introduced into the charge storage film 22 and act to terminate a shallow charge trap within the charge storage film 22. Accordingly, like region B of FIG. 13, a deep charge trap within the charge storage film 22 is left, so that even though the defect 50f is generated in the tunnel insulating film 21, the charges stored in the charge storage film 22 are difficult to be eliminated, and thus the data storage property can be improved.

For example, as illustrated in FIG. 14, when the impurities 50i are introduced into the tunnel insulating film 21, the impurities 50i are difficult to be eliminated by electrical stress of the write operation or the erase operation, compared to hydrogen. Accordingly, like region C of FIG. 14, the defects 50f are difficult to be generated within the tunnel insulating film 21 (the insulating films 21a, 21b, and 21c), so that the charges stored in the charge storage film 22 are difficult to be eliminated. Accordingly, the data storage property can be improved.

In the case where the block insulating film 23 includes a High-k material, when the impurities 50i are introduced to the block insulating film 23 during the introduction of the impurities 50i (the process of FIG. 7), the insulating property of the block insulating film 23 may be degraded at a high temperature or reducing atmosphere. Accordingly, the amount of introduced impurities 50i within the block insulating film 23 maybe small. That is, the average impurity concentration in the region Rbk of the block insulating film 23 is smaller than any one of the average impurity concentration in the region Rct of the charge storage film 22 and the average impurity concentration in the region Rtn of the tunnel insulating film 21.

In the exemplary embodiments illustrated in FIG. 1 to FIG. 11, the semiconductor memory device with an improved operation characteristic of the memory cell, and the method of manufacturing the same are provided.

In the exemplary embodiments illustrated in FIG. 1 to FIG. 11, the impurities 50i are introduced during the process of FIG. 7, but the impurities 50i may be introduced after the process of FIG. 10 or after the process of FIG. 11.

For example, when the cavities 61 are formed in the stacked body 15a by the removal of the sacrifice films 60 during the process of FIG. 10, the insulating film 23a may be exposed via the cavities 61. Then, the impurities 50i may be introduced from the exposed insulating film 23a side.

For example, during the process of FIG. 11, the insulating films 23b and the electrode films 40 may be formed on the internal surfaces of the cavities 61. Then, the impurities 50i may be introduced via the insulating films 23b and the electrode films 40.

After the process of FIG. 10 or after the process of FIG. 11, the impurities 50i may be introduced by the heat treatment described in the process of FIG. 7. The heat treatment condition may be the same as the condition described in the process of FIG. 7. By the heat treatment, the impurities 50i are introduced so as to form the concentration distribution illustrated in FIG. 5. That is, the impurities 50i may be introduced so that the average impurity concentration in the region Rct of the charge storage film 22 is higher than the average impurity concentration in the region Rtn of the tunnel insulating film 21, and the average impurity concentration in the region Rtn of the tunnel insulating film 21 is higher than the average impurity concentration in the region Rbk of the block insulating film 23.

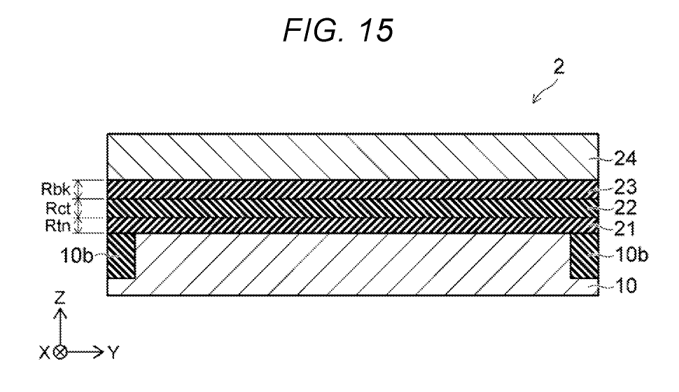

FIG. 15 is a cross-sectional view of a semiconductor memory device 2 according to a second exemplary embodiment.

The semiconductor memory device 2 according to the exemplary embodiment illustrated in FIG. 15 corresponds to a planar semiconductor memory device unlike the semiconductor memory device 1 having the three-dimensional structure according to the first exemplary embodiment. Hereinafter, an exemplary embodiment in which impurities 50i are included in the planar semiconductor memory device 2 will be described.

As illustrated in FIG. 15, the semiconductor memory device 2 is provided with a substrate 10, a tunnel insulating film 21, a charge storage film 22, a block insulating film 23, and an electrode film 24. An element isolation region 10b is provided on the substrate 10.

As illustrated in FIG. 15, the tunnel insulating film 21 is provided on the substrate 10 having the element isolation region 10b. The charge storage film 22 is provided on the tunnel insulating film 21. The block insulating film 23 is provided on the charge storage film 22. The electrode film 24 is provided on the block insulating film 23.

The impurities 50i may be included in each of a region Rtn of the tunnel insulating film 21, a region Rct of the charge storage film 22, and a region Rbk of the block insulating film 23 at a predetermined concentration.

The average impurity concentration in the region Rct of the charge storage film 22 is higher than the average impurity concentration in the region Rtn of the tunnel insulating film 21. Further, the average impurity concentration in the region Rtn of the tunnel insulating film 21 is higher than the average impurity concentration in the region Rbk of the block insulating film 23.

Next, a method of manufacturing the semiconductor memory device according to the exemplary embodiments illustrated in FIG. 15 will be described.

First, the element isolation region 10b is formed on the substrate 10, and then the tunnel insulating film 21 is formed on the substrate 10 having the element isolation region 10b. The tunnel insulating film 21 is formed of, for example, silicon oxide. For example, the tunnel insulating film 21 is formed by heating the substrate 10 including silicon in a vapor atmosphere at about 750° C. For example, the film thickness (the thickness in the Z-axis direction) of the tunnel insulating film 21 is about 6 nm. The tunnel insulating film 21 may be a stacked film including a silicon oxide film and a silicon nitride film or a stacked film including a silicon oxynitride film and a silicon oxide film. When the tunnel insulating film 21 is formed in the form of a stacked film, hole injection efficiency during an erase operation can be improved.

Next, the charge storage film 22 is formed on the tunnel insulating film 21. The charge storage film 22 is formed of, for example, a silicon nitride. For example, the charge storage film 22 is formed by an LPCVD method by reacting the gases of dichlorosilane and ammonia at a temperature of about 650° C. For example, the charge storage film 22 is formed by an ALD method using the gases of dichlorosilane and ammonia.

Next, the block insulating film 23 is formed on the charge storage film 22. The block insulating film 23 is formed of, for example, silicon oxide. For example, the block insulating film 23 is formed by an ALD method at a temperature of about 450° C. In order to increase purity within the block insulating film 23, a short-time heat treatment may be performed at a temperature of about 1,000° C. Further, the block insulating film 23 may also be a stacked film of a silicon oxide film and an aluminum oxide film.

Next, the impurities 50i may be introduced into the tunnel insulating film 21, the charge storage film 22, and the block insulating film 23, for example, by heat-treating the substrate 10 at a gas atmosphere including the impurities 50i. As the conditions of the heat treatment, the heat treatment may be performed in, for example, a gas atmosphere including the impurities 50i at the temperature of about 900° C. for a processing time of about 30 minutes. Further, the introduction position of the impurities 50i may be selected such that a characteristic of each film is not degraded by the heat treatment and the introduced impurities are not eliminated by the thermal load of a post process.

Through the heat treatment, the impurities 50i may be introduced into each of the tunnel insulating film 21, the charge storage film 22, and the block insulating film 23 at a predetermined concentration. That is, the impurities 50i maybe introduced such that the average impurity concentration in the region Rct of the charge storage film 22 is higher than the average impurity concentration in the region Rtn of the tunnel insulating film 21, and the average impurity concentration in the region Rtn of the tunnel insulating film 21 is higher than the average impurity concentration in the region Rbk of the block insulating film 23.

The impurities 50i may be introduced through an ion implantation, instead of the heat treatment. As a processing condition by the ion implantation method, for example, the acceleration voltage is in the range of 1 keV or more and 100 keV or less, and the dose amount is in the range of 1E15 cm-² or more and 1E16 cm-² or less. Further, the heat treatment may be performed after the ion implantation.

A predetermined gas maybe made to flow during the film formation processes of the tunnel insulating film 21 and the charge storage film 22, and a gas including the impurities 50i may be introduced simultaneously with the film formation of the tunnel insulating film 21 and the charge storage film 22.

Next, the electrode film 24 is formed on the block insulating film 23. The electrode film 24 is formed of, for example, a metal material such as tungsten. The electrode film is formed of, for example, polysilicon. Then, the semiconductor memory device 2 according to the exemplary embodiment illustrated in FIG. 15 is manufactured.

Hereinafter, an example of a configuration of a NAND cell unit will be described.

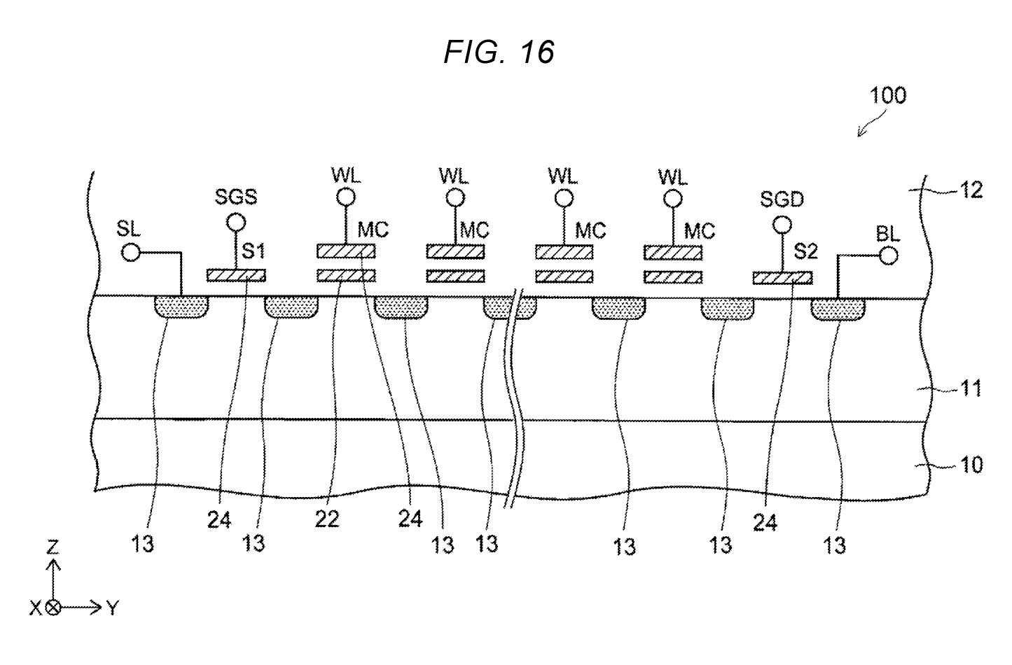

FIG. 16 is a cross-sectional view illustrating an example of a configuration of a NAND cell unit 100.

As illustrated in FIG. 16, the NAND cell unit 100 includes plural serially connected memory cells MC, and two select transistors S1 and S2 connected to both ends of the plural serially connected memory cells MC. The source-side select transistor S1 is connected to a source line SL, and the drain-side select transistor S2 is connected to a bit line BL.

The plural memory cells MC and the select transistors S1 and S2 are formed on a well 11 within a substrate 10, and are serially connected by diffusion layers 13 within the well 11. The transistors are covered by an interlayer insulating film 12.

Each of the plural memory cells MC has a charge storage film 22 and an electrode film 24. The charge storage film 22 is provided on the substrate 10 via the interlayer insulating film 12. The electrode film 24 is provided on the charge storage film 22 via the interlayer insulating film 12. The electrode film 24 of each of the memory cell MC configures a word line WL. The select transistors S1 and S2 include the electrode film 24 which may be formed on the substrate 10 via the interlayer insulating film 12. The electrode films 24 of the select transistors S1 and S2 configure a source-side select gate SGS and a drain-side select gate SGD, respectively.

The effect of the second exemplary embodiment is the same as the effect of the first exemplary embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a substrate;
a stacked body, provided on the substrate, including a plurality of electrode films stacked to be spaced apart from one another in a first direction; and
a columnar portion, provided within the stacked body, including a semiconductor portion extending in the first direction and a charge storage layer provided between the plurality of electrode films and the semiconductor portion,
wherein the columnar portion includes a first region between the plurality of electrode films and the charge storage layer, a second region having the charge storage layer, and a third region between the semiconductor portion and the charge storage layer,
the first region, the second region, and the third region include impurities,
an average impurity concentration of the third region is higher than an average impurity concentration of the first region.

2. The semiconductor memory device according to claim 1, wherein an average impurity concentration of the second region is higher than an average impurity concentration of the third region.

3. The semiconductor memory device according to claim 2, wherein the impurities include at least one of heavy hydrogen, fluorine, carbon, nitrogen, or selenium.

4. The semiconductor memory device according to claim 2, wherein the impurities include a compound having a cyano group.

5. The semiconductor memory device according to claim 2, wherein the columnar portion includes a first insulating film located in the first region and a second insulating film located in the third region,
the charge storage layer, the first insulating film, and the second insulating film include the impurities,
an average impurity concentration of the charge storage layer is higher than an average impurity concentration of the second insulating film, and
the average impurity concentration of the second insulating film is higher than an average impurity concentration of the first insulating film.

6. The semiconductor memory device according to claim 5, wherein
the charge storage layer includes silicon nitride, and
the first insulating film and the second insulating film include silicon oxide.

7. The semiconductor memory device according to claim 2, wherein charge storage layer extends in the first direction.

8. The semiconductor memory device according to claim 2, wherein a maximum impurity concentration of the second region is higher than a maximum impurity concentration of the third region.

9. A NAND cell comprising:
a well disposed on the substrate;
a diffusion layer disposed in the well; and
the semiconductor memory device according to claim 1, wherein:
the semiconductor memory device includes a plurality of memory cells each of which is formed at an intersection of a channel and one of the plurality of electrode films, and
the plurality of memory cells are disposed on the well on the substrate, and are connected by the diffusion layer in the well.

10. A method of manufacturing a semiconductor memory device, the method comprising:
forming a stacked body by alternately forming a first insulating film and a first film on a substrate;
forming a through via hole in the stacked body that extends in a stacking direction of the stacked body;
forming a second insulating film on an inner wall surface of the through via hole;
forming a charge storage layer on the second insulating film in the through via hole;
forming a third insulating film on the charge storage layer in the through via hole; and
forming impurities in the second insulating film, the charge storage layer, and the third insulating film,
wherein an average impurity concentration of the charge storage layer is higher than an average impurity concentration of the third insulating film, and
the average impurity concentration of the third insulating film is higher than an average impurity concentration of the second insulating film.

11. The method according to claim 10, wherein the impurities include at least one of heavy hydrogen, fluorine, carbon, nitrogen, or selenium.

12. The method according to claim 10, wherein the impurities include a compound having a cyano group.

13. The method according to claim 10, further comprising:
forming a semiconductor portion on the third insulating film in the through via hole;
forming slits in the stacked body so as to extend in the stacking direction and in a first direction which intersects the stacking direction along an upper surface of the substrate; and
removing the first film via the slit, and forming an electrode film within a cavity formed by the removing.

14. The method according to claim 13, further comprising:
forming impurities in a first region between the electrode film and the charge storage layer; and
forming impurities in a second region including the charge storage layer.

15. The method according to claim 14, further comprising:
forming impurities in a third region between the semiconductor portion and the charge storage layer,
wherein an average impurity concentration of the third region is higher than an average impurity concentration of the first region.

16. The method according to claim 15, wherein an average impurity concentration of the second region is higher than an average impurity concentration of the third region.

17. The method according to claim 10, wherein charge storage layer extends in the stacking direction.

18. The method according to claim 10, wherein a maximum impurity concentration of the charge storage layer is higher than a maximum impurity concentration of the third insulating film.

19. The method according to claim 10, wherein impurities are introduced by plasma doping using a plasma doping device.

20. The method according to claim 10, wherein impurities are introduced by heat-treating the substrate in a gas atmosphere including the impurities.
